(19) United States
(12) Patent Application Publication
(10) Pub. No.: US 2002/0196868 A1
(43) Pub. Date: Dec. 26, 2002

(54) Evaluation device for assessing a digital data signal, in particular a data signal for a semiconductor memory circuit

(76) Inventors: Hermann Ruckerbauer, Moos (DE); Andre Schaefer, Munchen (DE)

Correspondence Address: LERNER AND GREENBERG, P.A., Post Office Box 2480, Hollywood, FL, 33022-2480, US

(21) Appl. No.: 10/178,694

(22) Filed: Jun. 24, 2002

(30) Foreign Application Priority Data
Jun. 23, 2001 (DE) 101 30 361.0

(51) Int. Cl. H03K 9/00; H04L 27/06

(52) U.S. Cl. 375/316; 375/340

(57) ABSTRACT

The invention relates to an evaluation device for assessing a digital data signal having a sampling device, a processing unit and a data memory. The sampling device is configured to sample the data signal multiply in a temporally offset manner within a predetermined time period and to store the samples of the data signal in the data memory. The processing unit is configured to output a data value of the data signal in a manner dependent on the samples at an output of the evaluation device.

### BACKGROUND OF THE INVENTION

1. Field of the Invention

The invention relates to an evaluation device and a method for assessing a digital data signal, in particular, for a semiconductor memory circuit.

Particularly when a semiconductor memory circuit is operated at high frequencies, interference factors, such as e.g. signal crosstalk, electromagnetic pulses or the like, can make it more difficult to identify an input signal. The assessment of the input signal as a logic “1” or “0” is thereby made more difficult.

In a specific specification, specific reference voltage levels are defined for input signals. If the input signal is intended to be read, a comparison is effected to find out whether the voltage level of the input signal lies above or below a specific reference voltage prescribed by the specification. As a result of this comparison, a decision is made as to whether the input signal represents a logic “0” or “1”. Because of very diverse influences that occur in a real system (noise, skew, crosstalk, SSI or the like), brief signal fluctuations arise that can lead to errors. Such errors can also arise if the data eye is shifted relative to the sampling instant. This shifting of the data eye relative to the sampling instant is particularly undesirable if the data eye of the input signal becomes smaller on account of interference.

Because of these influences, errors can arise in the interpretation of data in the receiver circuit of a semiconductor memory circuit.

### SUMMARY OF THE INVENTION

It is accordingly an object of the invention to provide an evaluation device a method for assessing a digital data signal which overcomes the above-mentioned disadvantages of the prior art apparatus and methods of this general type.

In particular, it is an object of the invention to increase the reliability of the assessment of the digital data signal.

With the foregoing and other objects in view there is provided, in accordance with the invention, an evaluation device for assessing a digital data signal. The evaluation device includes: a sampling device; a processing unit; a data memory; and an output. The sampling device is configured to obtain samples by sampling the data signal a plurality of times in a temporally offset manner within a predetermined time period. The sampling device stores the samples in the data memory. The processing unit is configured to provide, at the output, a data value of the data signal in a manner dependent on the samples.

In accordance with an added feature of the invention, the sampling unit includes a plurality of sampling devices that are configured with respect to one another so as to receive the data signal in a temporally offset manner.

In accordance with an additional feature of the invention, the predetermined time period is not greater than a maximum time range required for transmitting a datum.

In accordance with another feature of the invention, the sample that is stored the most often in the data memory is output by the processing unit as the data value.

In accordance with a further feature of the invention, the sampling device uses a validity signal to start the sampling of the data signal in the temporally offset manner.

In accordance with a further added feature of the invention, the processing unit uses the samples stored in the data memory to determine a temporal offset of the data signal relative to the validity signal.

In accordance with yet an added feature of the invention, the digital data signal is for a semiconductor memory circuit.

With the foregoing and other objects in view there is provided, in accordance with the invention, a method for assessing a digital data signal. The method includes steps of: sampling the data signal a plurality of times in a temporally offset manner within a predetermined time period; storing the samples; determining a data value in a manner dependent on the samples that are stored; and outputting a data value that is assigned to a datum of the data signal.

In accordance with an added mode of the invention, the step of determining the data value is performed by allocating a value of a most frequent sample to the data value.

In accordance with an additional mode of the invention, the predetermined time period is not greater than a maximum time range in which a datum of the data signal is transmitted.

In accordance with another mode of the invention, a validity signal is used to start performance of the sampling of the data signal.

The invention provides an evaluation device for assessing a digital data signal, in particular, a digital signal for a semiconductor memory circuit. The evaluation device has a sampling device, a processing unit, and a data memory. The sampling device is configured to sample the data signal multiply in a temporally offset manner within a predetermined time period and to store the samples of the data signal, which are preferably converted into logic values, in the data memory. The processing unit is configured to provide, at an output of the evaluation device, a data value of the data signal in a manner dependent on the samples.

A further aspect of the present invention provides a method for assessing a digital data signal. The digital data signal is sampled multiply in a temporally offset manner within a predetermined time period and the samples are preferably stored as digital values. Afterward, a data value is determined and output in a manner dependent on the stored samples.

The invention thus provides for the data signal to be evaluated at a plurality of instants, in contrast to conventional evaluation devices in which only a fixed instant is used for receiving the data signal. If the samples of the received data signal are present, then it is possible, e.g. by using a function executed in a processing unit, to decide which data value the data signal had at the sampling instant. The plurality of samples can be assessed, for example, according to the mean value principle or similar processing specifications.

The advantage of the evaluation device and of the method is that the present data value of the data signal can be determined more reliably by virtue of the multiple sampling of the data signal in a specific time period. Even if a portion of the samples is detected erroneously, the data value of the data signal can be interpreted reliably using the remaining samples.

In order, in the case of fast signals, to enable sampling at short intervals with respect to one another, the evaluation device may be provided with a plurality of sampling devices that are arranged along a data line with respect to one another so as to receive the data signal in a temporally offset manner. Since propagation times can be set very exactly by the line lengths, it is possible in this way to arrange a plurality of sampling devices along a signal path, so that the signal can be successively received in the sampling devices. The sampling is then effected by all the sampling devices performing a sampling simultaneously, for example, in a manner separated by a carrier signal, so that each of the sampling devices takes up a temporally offset sample.

In order to ensure that the sampling device samples the data signal only for one data value, the predetermined time period may correspond to less than or equal to the maximum time range required for transmitting a datum. It can thus be ensured that the sampling is not effected over a plurality of successive data values of the data signal.

The processing unit uses the samples to determine the data value of a respective datum of the data signal. For this purpose, the processing unit may be embodied to output the sample, which is stored the most often in the data memory, as the data value.

The sampling device is embodied to start the temporally offset sampling of the data signal by using a validity signal. Such a validity signal is available for example in conventional synchronous data systems. A data signal is sampled using an edge of a validity signal. In this case, the occurrence of the edge determines the sampling instant. According to the invention, a plurality of temporally offset sampling processes are now started by the validity signal. As a result, samples are detected in a sequence beginning with the edge of the validity signal.

The processing unit is embodied such that it can temporally offset the validity signal with a specific offset duration. This is usually carried out when the processing unit ascertains that the data eye of the data signal is offset to an excessively great extent relative to the edge of the validity signal. In this case, it is expedient to temporally delay the validity signal in such a way that the corresponding edge essentially occurs at the beginning of the data eye or at an instant that is the most suitable for the multiple sampling.

Other features which are considered as characteristic for the invention are set forth in the appended claims.

Although the invention is illustrated and described herein as embodied in an evaluation device for assessing a digital data signal, in particular a data signal for a semiconductor memory circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of a preferred embodiment of the present invention;

FIG. 2 is an eye diagram for illustrating the sampling of the data value; and

FIG. 3 is a block diagram of another preferred embodiment of the present invention having multiple sampling devices.

### DESCRIPTION OF THE PREFERRED EMBODIMENTS

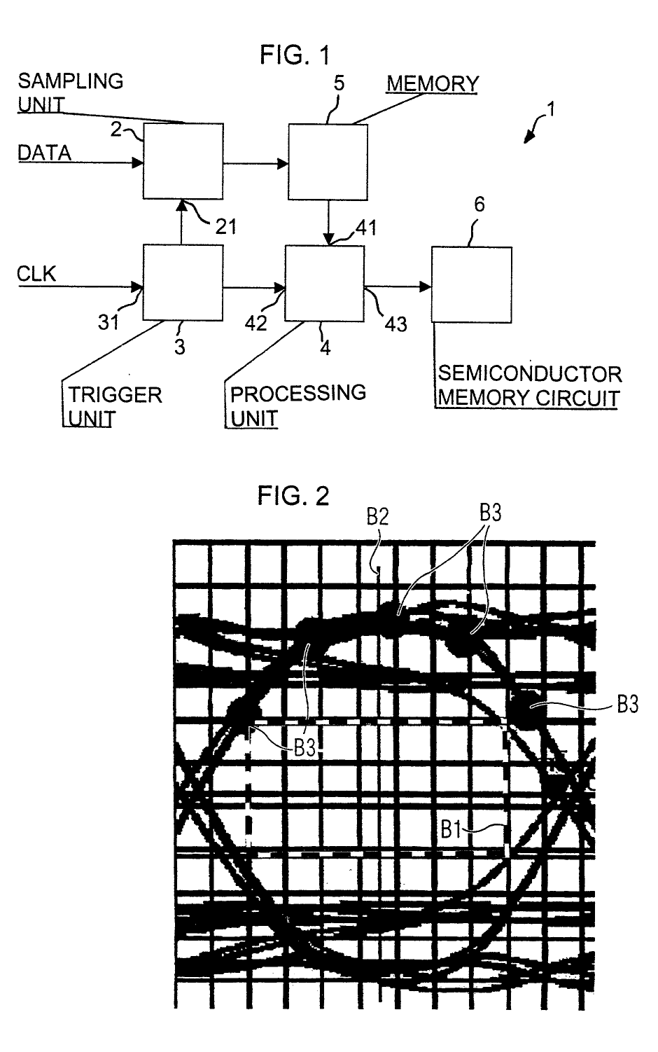

Referring now to the figures of the drawing in detail and first, particularly, to FIG. 1 thereof, there is shown a block diagram of an inventive evaluation device 1 in which a data value DATA is intended to be assessed. Such an evaluation device is provided, for example, as an input circuit for a semiconductor memory circuit 6, but can generally be used in integrated circuits. Data values are usually transmitted in a data stream in which the respective data values are synchronous with respect to a clock signal or with respect to edges of a clock signal CLK. In other words, upon the occurrence of a specific, e.g. rising, edge of the clock signal CLK, a specific data value of the data stream is sampled. The next data value can then usually be sampled with the corresponding next rising edge.

The evaluation device 1 has a sampling unit 2 that assigns an instantaneous data value to an analog value of the data stream, e.g. a voltage value. The instantaneous data value is determined, for example, by comparing the instantaneous analog value or voltage level of the data stream with a reference value or reference voltage level and allocating a data value, depending on whether the instantaneous voltage level of the data stream lies above or below the reference voltage level. By way of example, if the instantaneous voltage level of the data stream lies above the reference voltage level, then the instantaneous data value is a logic “1”, and if the instantaneous voltage level lies below the reference voltage level, then the instantaneous data value is a logic “0”.

The sampling unit 2 has a trigger input 21. A trigger signal present at the trigger input 21 specifies the instants at which a sampling of the data stream is carried out by the sampling unit 2. Thus, at instants which are specified by the trigger signal, the data stream is in each case sampled once and an instantaneous voltage level is determined. The instantaneous voltage level is compared with a reference voltage level and a data value is allocated, as previously described.

The trigger input 21 of the sampling unit 2 is connected to a trigger unit 3. The trigger unit 3 has a clock input 31, at which the clock signal CLK is present. In the trigger unit 3, the clock signal CLK causes a number of successive trigger pulses to be output to the trigger input 21 of the sampling unit 2. The temporal duration of the sequence of the trigger signals that are generated in the trigger unit 3 is essentially approximately the customary time duration for which a data value of the data stream is present at the sampling unit 2. This may be, for example, in the case of a conventional synchronous data transmission, the time duration of a clock cycle of the clock signal, or in the case of e.g. a double data rate data transmission, the time duration of half a clock cycle of the clock signal CLK. The temporal interval between the trigger pulses depends on the desired number of the trigger pulses with which a datum in a data stream is intended to be sampled.

The instantaneous data values sampled in the sampling unit 2 are buffer-stored in a data memory 5 so that a sequence of successive samples of the data stream is present there. A register memory is preferably used for the data memory 5, in order to provide high write and read speeds. Using a multiplexing unit (not shown), the data are fed to the memory cells of the register memory. The multiplexing unit can be controlled by the trigger unit 3.

As soon as a datum being transmitted in the data stream has been completely sampled, the samples are read from the data memory 5 by a processing unit 4 via the data input 41. The processing unit 4 receives the data stored in the data memory 5 and determines therefrom the data value of the data signal DATA present. The data value is output to the semiconductor memory circuit 6 via the data output 43 at the processing unit 4. In order for the processing unit 4 to identify the instant at which the datum of the data stream is sampled for the last time, the processing unit 4 has a control input 42 that is connected to the trigger unit 3. The trigger unit 3 signals to the processing unit 4, via the control input 42, when the last sampling of the respective datum of the data stream is effected. The processing unit 4 is thereby informed that the last sample of the sequence is now being written to the data memory 5 and that an evaluation of the stored samples can be carried out.

Given a magnitude of a data eye of approximately 2 ns length, an assessment of the data signal can be carried out every 500 ps, for example. The samples can be stored in the data memory 5 and an assessment of the data signal can be carried out. An assessment of the data signal can be carried out, for example, using the majority principle, according to which the datum is allocated the data value which is stored the most often in the data memory 5. An assessment can also be carried out by forming a mean value or by using other methods.

By way of example, if the values “01110”(in the order of their sampling) are stored in the data memory 5, then the data value “1” is accordingly allocated to the corresponding datum. It is evident that although some of the samples have yielded a logic “0”, the data value of the datum is interpreted as logic “1”. Thus, it is no longer absolutely necessary for the correct data value of the datum to be present at the instant of a single sampling. If, in the present example, the values “11011” are stored in the data memory 5, then the datum is likewise assigned the data value “1” even though a “0” was sampled at an instant lying within the data eye of the datum. This may have been caused, for example, because of instances of signal coupling-in or other adverse influences on the data line.

Depending on the pattern of the stored samples, it is likewise possible to ascertain whether the clock signal is phase-shifted relative to the data stream. In this case, by way of example, “11100” or “00111” might be produced as sequence of the stored samples for the above-described example with five samplings. It is evident that the data eye occurs too early or too late relative to the clock signal, and it is possible, by using a suitable synchronizing device, to synchronize the clock signal relative to the incoming data stream, for example, by using a delay device.

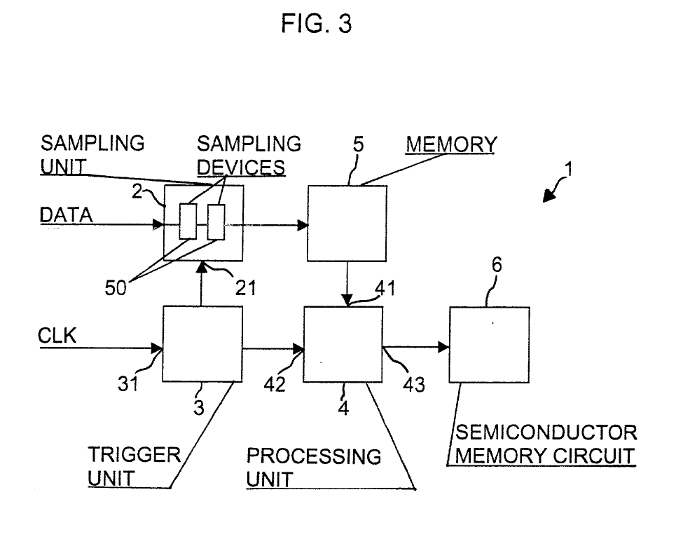

As shown in FIG. 3, the sampling unit 2 can also be constructed from a plurality of sampling devices 50 that are situated in a manner arranged one after the other on a data line on which the data stream is applied. They are arranged in each case such that a predetermined length of the data line lies between them. When the data stream is applied to the plurality of sampling devices, the datum is present successively in a temporally offset manner at the sampling devices. The sampling devices are then activated simultaneously by the trigger unit 3, so that the instantaneous data value is simultaneously sampled at all the sampling devices. Each of the sampling devices detects and interprets the instantaneous voltage level. The instantaneous voltage levels at the different positions of the data line correspond to the temporally offset voltage levels of the data signal.

FIG. 2 shows an eye diagram in which the data are valid within the rectangle B1 shown by the dashed lines. In order to comply with setup and hold times of the receiving device, the optimum instant for the sampling of the data is indicated by the vertical line B2 in the center of this window. The points B3 illustrated along the signal profile show the sampled voltage levels at the respective sampling time. The sampling instants are preferably chosen such that they are arranged around the optimum instant. In particular, the same number of samplings can be effected before and after the center point of the data eye. The voltage levels are assessed and an instantaneous logic data value is assigned, as described.

The sampling unit 2 can also sample the data stream continuously, in order to determine the optimum instant for a carrier signal by using the temporal sequence of the successively transmitted data. In addition, the continuously determined samples may be evaluated by the processing unit 4, so that data values can be allocated to specific sequences of logic “1”s and “0”s. To that end, the samples can be stored in a ring data memory that continuously stores the samples in a predefined memory area. If the memory area has been completely written to, the respective oldest samples are overwritten by the newest samples.

The features of the invention that are disclosed in the above description and in the drawings may be used both individually and in any desired combination for realizing various embodiments of the invention.

We claim:

1. An evaluation device for assessing a digital data signal, comprising:
a sampling device;
a processing unit;
a data memory, and
an output;
said sampling device being configured to obtain samples by sampling the data signal a plurality of times in a temporally offset manner within a predetermined time period;
said sampling device storing the samples in said data memory; and
said processing unit being configured to provide, at said output, a data value of the data signal in a manner dependent on the samples.

2. The evaluation device according to claim 1, wherein:
said sampling unit includes a plurality of sampling devices that are configured with respect to one another so as to receive the data signal in a temporally offset manner.

3. The evaluation device according to claim 1, wherein:
the predetermined time period is not greater than a maximum time range required for transmitting a datum.

4. The evaluation device according to claim 1, wherein:
a sample that is stored most often in said data memory is output by said processing unit as the data value.

5. The evaluation device according to claim 1, wherein:
said sampling device uses a validity signal to start the sampling of the data signal in the temporally offset manner.

6. The evaluation device according to claim 5, wherein:
said processing unit uses the samples stored in said data memory to determine a temporal offset of the data signal relative to the validity signal.

7. The evaluation device according to claim 1, wherein: the digital data signal is for a semiconductor memory circuit.

8. A method for assessing a digital data signal, which comprises:
sampling the data signal a plurality of times in a temporally offset manner within a predetermined time period;
storing the samples;
determining a data value in a manner dependent on the samples that are stored; and
outputting a data value that is assigned to a datum of the data signal.

9. The method according to claim 8, which comprises: performing the step of determining the data value by allocating a value of a most frequent sample to the data value.

10. The method according to claim 8, wherein: the predetermined time period is not greater than a maximum time range in which a datum of the data signal is transmitted.

11. The method according to claim 8, which comprises:
using a validity signal to start performance of the sampling of the data signal.

12. The method according to claim 8, wherein: the data signal is for a semiconductor memory circuit.
